(19) United States
(12) Patent Application Publication
(10) Pub. No.: US 2026/0361302 A1
(43) Pub. Date: Nov. 12, 2026

(54) RADIO FREQUENCY SWITCH WITH BODY CURRENT MANAGEMENT CIRCUIT

(71) Applicant: MEDIATEK INC., Hsinchu City (TW)

(72) Inventors: Samuel Gibson, Cambridge (GB); Bernard Mark Tenbroek, Cambridge (GB); Khalid Ali Abu El Yazid Eissa, Cambridge (GB)

(73) Assignee: MEDIATEK INC., Hsinchu City (TW)

(21) Appl. No.: 19/350,881

(22) Filed: Oct. 6, 2025

Related U.S. Application Data
(60) Provisional application No. 63/801,221, filed on May 7, 2025.

(51) Int. Cl. H03K 17/16; H03K 17/12; H03K 17/30; H03K 17/74

(52) U.S. Cl. CPC H03K 17/162; H03K 17/122; H03K 17/302; H03K 17/74

(57) ABSTRACT

A radio frequency (RF) switch includes a first field-effect transistor (FET) that is part of an RF switch FET stack. The first FET has a source, a drain, a gate, and a body. The gate of the first FET is connected to a gate bias network that is configured to control an on/off state of the RF switch FET stack. The RF switch further includes a first body current management (BCM) FET and a second BCM FET each having a source, a drain, and a gate. The drains of the first BCM FET and the second BCM FET are coupled to the body of the first FET, and the gates of the first BCM FET and the second BCM FET are coupled to the gate bias network.

### INCORPORATION BY REFERENCE

This application claims the benefit of U.S. Provisional Application No. 63/801,221, filed on May 7, 2025, which is incorporated herein by reference in its entirety.

### TECHNICAL FIELD

The present disclosure relates to high power radio frequency (RF) switch.

### BACKGROUND

High power radio frequency (RF) switches are components in wireless communication devices used to provide switching functionality between different signal paths. A common implementation of these switches uses field-effect transistors (FETs) arranged in stacked configurations (coupled in series). These RF switch FET stacks must handle high power signals while maintaining linearity and preventing harmonic distortion, particularly when operating in an off-state where the switch is effectively open and blocks signal transmission.

### SUMMARY

Aspects of the disclosure provide a radio frequency (RF) switch. The RF switch can include a first field-effect transistor (FET) that is part of an RF switch FET stack. The first FET has a source, a drain, a gate, and a body. The gate of the first FET is connected to a gate bias network that is configured to control an on/off state of the RF switch FET stack. The RF switch further includes a first body current management (BCM) FET and a second BCM FET each having a source, a drain, and a gate. The drains of the first BCM FET and the second BCM FET are coupled to the body of the first FET, and the gates of the first BCM FET and the second BCM FET are coupled to the gate bias network.

In one embodiment, the sources of the first BCM FET and the second BCM FET are coupled directly or indirectly to different nodes in the RF switch FET stack. In one embodiment, the gates of the first BCM FET and the second BCM FET are coupled to the gate of the first FET. In one embodiment, the RF switch further include a second FET and a third FET that are part of the RF switch FET stack. The second FET, the first FET, and the third FET are coupled in series, the source of the first FET is coupled to a drain of the second FET, and the drain of the first FET is coupled to a source of the third FET. A source of the first BCM FET is coupled to a source of the second FET, and a source of the second BCM FET is coupled to a drain of the third FET.

In one embodiment, the RF switch further includes a second FET and a third FET in the RF switch FET stack and a first resistor. The second FET, the first FET, and the third FET are coupled in series, the source of the first FET is coupled to a drain of the second FET, and the drain of the first FET is coupled to a source of the third FET. The first resistor is coupled between a source of the first BCM FET and a source of the second FET.

In one embodiment, the RF switch further comprises a second resistor that is coupled between a source of the second BCM FET and a drain of the third FET. In one embodiment, the RF switch further comprises one or more diodes connected in series that are coupled between the source of the first BCM FET and the source of the second FET in series with the first resistor.

In one embodiment, the RF switch includes a second FET and a third FET in the RF switch FET stack and one or more first diodes. The second FET, the first FET, and the third FET are coupled in series, the source of the first FET is coupled to a drain of the second FET, and the drain of the first FET is coupled to a source of the third FET. The one or more first diodes are connected in series and coupled between a source of the first BCM FET and a source of the second FET. In one embodiment, the RF switch further includes one or more second diodes connected in series that are coupled between a source of the second BCM FET and a drain of the third FET.

In one embodiment, the RF switch further includes 5 FETs in the RF switch FET stack that each include a source and a drain and are coupled in series. The first FET is the middle one of the 5 FETs, and the source and the drain of each pair of neighboring ones of the 5 FETs are coupled together. A source of the first BCM FET is coupled to the source of the first one of the 5 FETs, and a source of the second BCM FET is coupled to the drain of the last one of the 5 FETs.

In one embodiment, the RF switch further includes N FETs in the RF switch FET stack that each include a source and a drain and are coupled in series. N is an integer greater than 2, and the source and the drain of each pair of neighboring ones of the N FETs are coupled together. A source of the first BCM FET is coupled to a source or drain of a non-adjacent FET in the RF switch FET stack, and a source of the second BCM FET is coupled to a source or drain of another non-adjacent FET in the RF switch FET stack.

In one embodiment, the RF switch further includes 5 FETs in the RF switch FET stack and a first resistor. The 5 FETs each include a source and a drain and are coupled in series, the first FET is the middle one of the 5 FETs, and the source and the drain of each pair of neighboring ones of the 5 FETs are coupled together. The first resistor is coupled between a source of the first BCM FET and a source of the first one of the 5 FETs. In one embodiment, the RF switch further includes a second resistor that is coupled between a source of the second BCM FET and a drain of the last one of the 5 FETs. In one embodiment, the RF switch further includes one or more diodes connected in series that are coupled between the source of the first BCM FET and the source of the first one of the 5 FETs in series with the first resistor.

In one embodiment, the RF switch further includes 5 FETs in the RF switch FET stack and one or more first diodes. The 5 FETs each include a source and a drain and are coupled in series, the first FET is the middle one of the 5 FETs, and the source and the drain of each pair of neighboring ones of the 5 FETs are coupled together. The one or more first diodes are connected in series and coupled between a source of the first BCM FET and a source of the first one of the 5 FETs. In one embodiment, the RF switch further includes one or more second diodes connected in series that are coupled between a source of the second BCM FET and a drain of the last one of the 5 FETs.

Aspects of the disclosure provide a wireless communication device. The wireless communication device can include an RF switch. The RF switch can include a first field-effect transistor (FET) that is part of an RF switch FET stack. The first FET has a source, a drain, a gate, and a body. The gate of the first FET is connected to a gate bias network that is configured to control an on/off state of the RF switch FET stack. The RF switch further includes a first body current management (BCM) FET and a second BCM FET each having a source, a drain, and a gate. The drains of the first BCM FET and the second BCM FET are coupled to the body of the first FET, and the gates of the first BCM FET and the second BCM FET are coupled to the gate bias network.

### BRIEF DESCRIPTION OF THE DRAWINGS

Various embodiments of this disclosure that are proposed as examples will be described in detail with reference to the following figures, wherein like numerals reference like elements, and wherein:

FIG. 1 is a diagram showing a section of an RF switch, illustrating an RF switch circuit with a FET stack and a body current management (BCM) circuit using diode stacks for body current management.

FIG. 2 is a diagram showing a section of another RF switch, illustrating an RF switch circuit with a replica BCM circuit that includes diode stacks and a resistor string for creating replica body voltages.

FIG. 3 is a diagram showing a section of an RF switch according to some embodiments of the present disclosure, illustrating an RF switch circuit with a BCM circuit using BCM FETs, where each switch FET in the FET stack is associated with a pair of BCM FETs.

FIG. 4 is a diagram showing another embodiment of an RF switch with BCM FETs according to the present disclosure, where the sources of the BCM FETs are coupled to non-adjacent switch FETs in the FET stack.

FIG. 5 is a graph showing test results comparing the third harmonic power performance of RF switches with different body current management schemes, including FET BCM, diode BCM, replica BCM, and no BCM configurations.

FIG. 6 is a graph showing improved drain-body/source-body junction bias voltages of a switch FET when using FET BCM compared to configurations with no BCM, demonstrating the body-source voltage relationship with applied RF input power.

FIG. 7 is a diagram showing an example mobile device implementing an RF front-end according to embodiments of the present disclosure, illustrating the use of RF switches with FET BCM in various components including antenna tuners, cross switches, and antenna switches.

### DETAILED DESCRIPTION OF EMBODIMENTS

The body current de-biasing mechanism contributes to the degradation of linearity in radio frequency (RF) switch field-effect transistors (FETs) and imposes a limitation on the maximum RF power that can be applied to the RF switch in its off state. When a high-power RF signal is applied to an input terminal of an off-state RF switch stack, large electric fields can be generated within the FETs of the switch. These electric fields may induce tunneling and impact ionization, resulting in body currents within the FETs.

The body currents typically flow through a high-resistance body bias resistor, causing a voltage drop across the body bias resistor due to the current-resistance (IR) effect. This voltage drop raises the body voltage of the FET, thereby reducing the reverse bias across the drain-body and source-body junctions and potentially forward-biasing the junctions. As a result, the RF switch may enter a low-impedance state and become susceptible to early onset breakdown. Moreover, the junction’s bias dependence on signal power causes the junction capacitance to vary with the signal swing, generating harmonic currents that further degrade the linearity of the RF switch stack.

The present disclosure provides FET body current management (BCM) circuits and techniques configured to reroute body current away from body bias resistors and toward a source, drain, or drain-source resistor node located further down the RF switch stack. For example, when high RF power is applied to the RF switch stack, impact ionization may generate body current that exits a switch FET via its body contact. As this current flows through a body bias resistor, the resulting voltage drop raises the body voltage of the switch FET. While the body voltage rising, a BCM FET coupled to the body of the switch FET starts to operate. The body current is then redirected through the BCM FET to other components in the RF switch stack, where the energy is dissipated.

The BCM circuits and techniques improve the linearity of the RF switch FETs, extend the maximum RF power level for linear operation, and increase the off-state withstand voltage of the switch. The RF signal power or voltage threshold at which the BCM circuit activates can be adjusted by selecting the size and threshold voltage (Vt) of the BCM FET, or by using alternative circuit embodiments as described below. The BCM circuit can be integrated with each individual switch FET to form a unit cell, which allows the technique to be scaled for any desired switch stack height (the number of FETs in the switch stack).

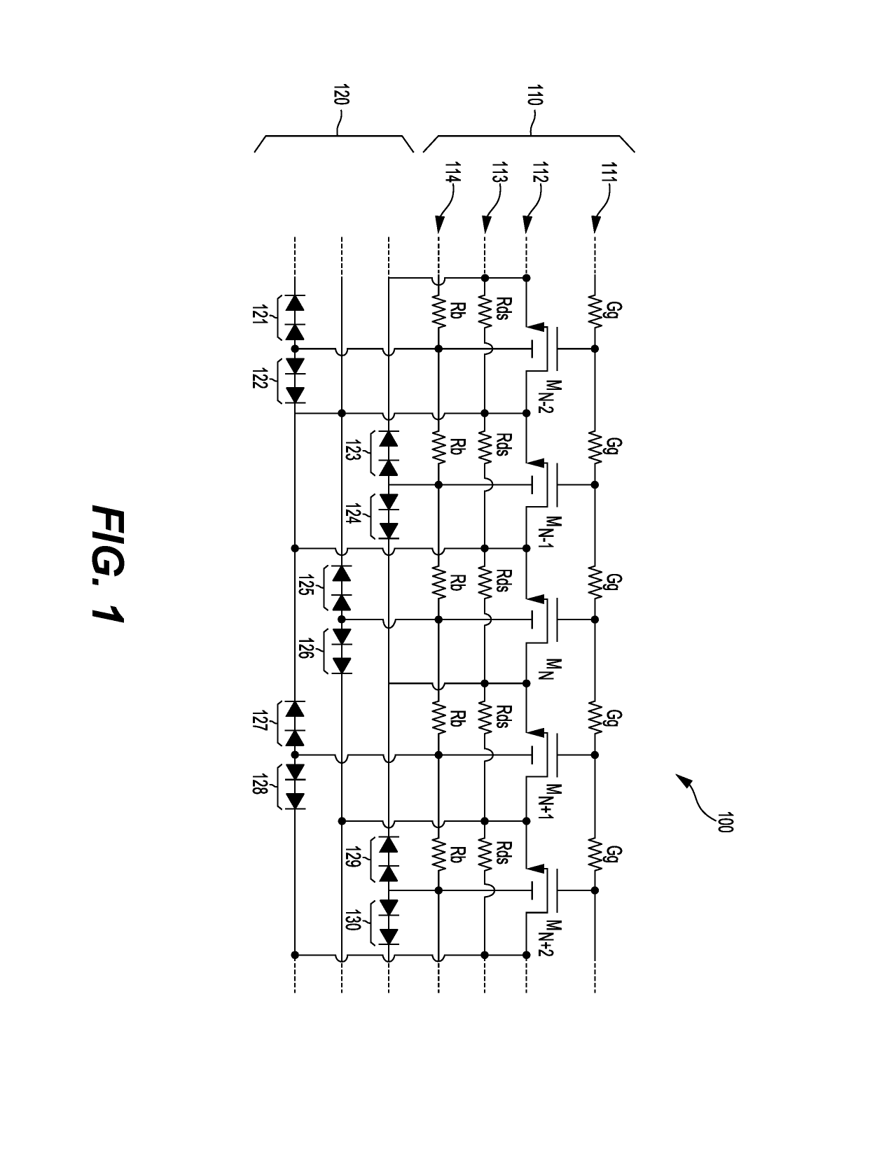

FIG. 1 shows a diagram of a section of an RF switch 100. The RF switch 100 includes an upper portion that is an RF switch circuit 110 and a lower portion that is a BCM circuit 120. The RF switch circuit 110 includes a gate bias network 111, a FET stack 112, a drain-to-source resistor network 113, and a body bias network 114. The FET stack 112 includes FETs M_{N-2} through M_{N+2} connected in series. The FETs each share a portion of an RF load voltage applied across the FET stack 112. The RF switch 100 can have a first port and second port (not shown). The FET stack can be arranged between these two ports. The gate bias network 111 supplies bias voltages to the gates of the respective FETs via a series of gate bias resistors Rg. The drain-to-source resistor network 113 includes drain-to-source resistors Rds that distribute portions of the RF load voltage across the FET stack 112 to each FET. The body bias network 114 supplies body bias voltages to the FETs through a series of body bias resistors Rb. The RF switch 100 can have third and fourth ports to provide a DC bias to the gate bias network 111 and the body bias network 114. The DC voltage levels on the third and fourth port determine the operating condition of the RF switch.

The BCM circuit 120 includes diode stacks 121-130 with each FET in the FET stack 112 associated with a pair of diode stacks. For example, for FET M_{N}, a diode stack 125 has an anode coupled to the body of the FET M_{N} and a cathode coupled to a source of the FET M_{N-1}; and a diode stack 126 has an anode coupled to the body of the FET M_{N} and a cathode coupled to a drain of the FET Mₙ₊₁. The diode stacks 121-130 can each include one or more than two diodes in some examples.

In operation, the RF switch 100 can be placed into an off state (i.e., open) by applying suitable gate voltages to each FET in the FET stack 112 through the gate bias network 111. When a high RF voltage is applied to the RF switch 100, body current may be generated within one or more FETs in the FET stack 112. Taking the FET M_{N} as example, the body current initially flows through the corresponding body bias resistor Rb, raising the body voltage of the FET M_{N}. As the body voltage increases beyond a certain threshold, the corresponding diode stack 125 becomes forward-biased and start conducting. The body current is then diverted away from the body bias resistor Rb and rerouted through the diode stack 125. In this way, the BCM circuit 120 can maintain the body voltage at a more stable level in response to RF voltage swings, thereby reducing signal non-linearity and avoiding early breakdown of the RF switch FETs. The BCM mechanism of the RF switch 100 is based on diode stacks and thus is referred to as diode BCM.

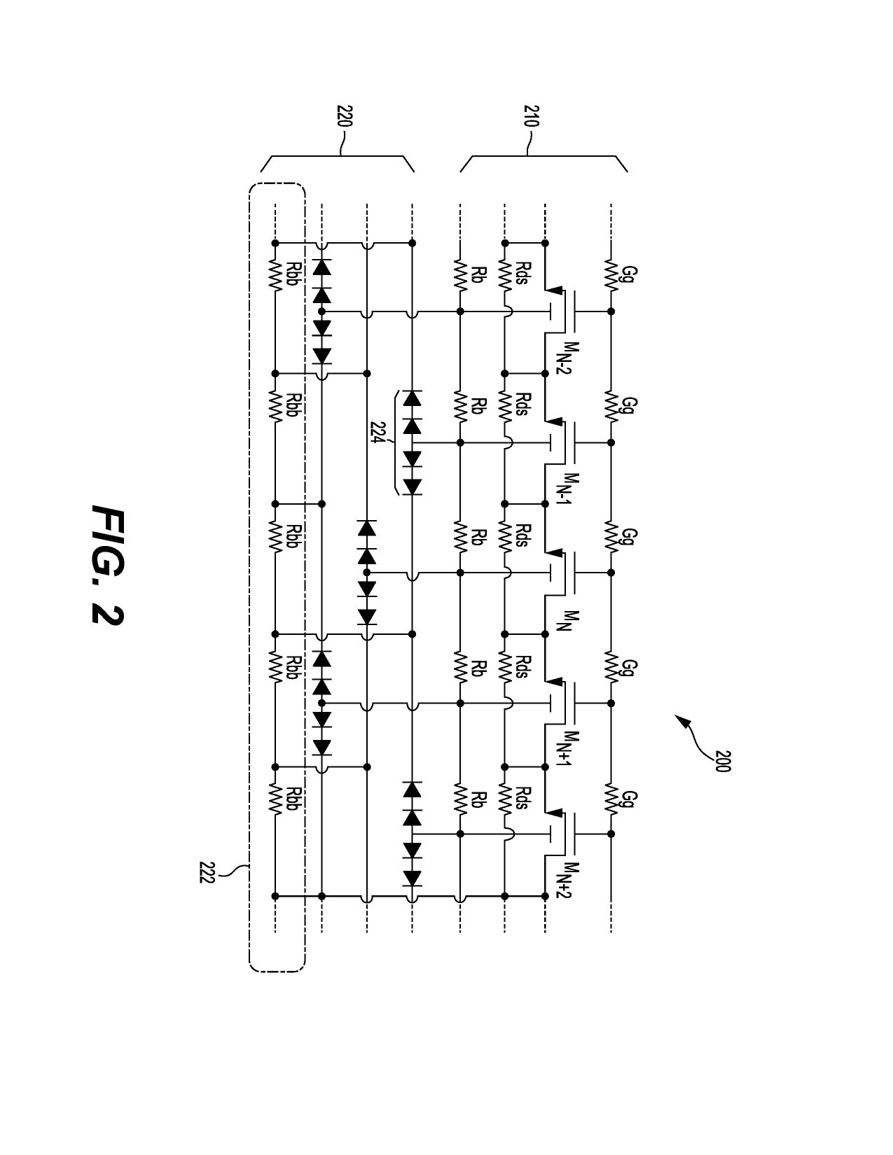

FIG. 2 shows a diagram of a section of another RF switch 200. An upper portion of the RF switch 200 is an RF switch circuit 210 and has similar components and circuit structures as the upper portion of the RF switch 100 (circuit components 111, 112, 113, and 114). A lower portion of the RF switch 200 is a BCM circuit 220 configured to reroute FET body current. The BCM circuit 220 includes a pair of diode stacks 224 for each FET in the RF switch 200, similar to the configuration in FIG. 1. The BCM circuit 220 further includes a resistor string 222 (resistors Rbb connected in series). Cathodes of the pair of diode stacks are coupled to nodes in the resistor string 222. In operation, the BCM circuit 220 diverts body currents away from body bias resistors Rb through the diode stacks 224 into the resistor string 222. Because a resistor string is used to create replica body voltages, the BCM mechanism of the RF switch 200 is referred to as replica BCM.

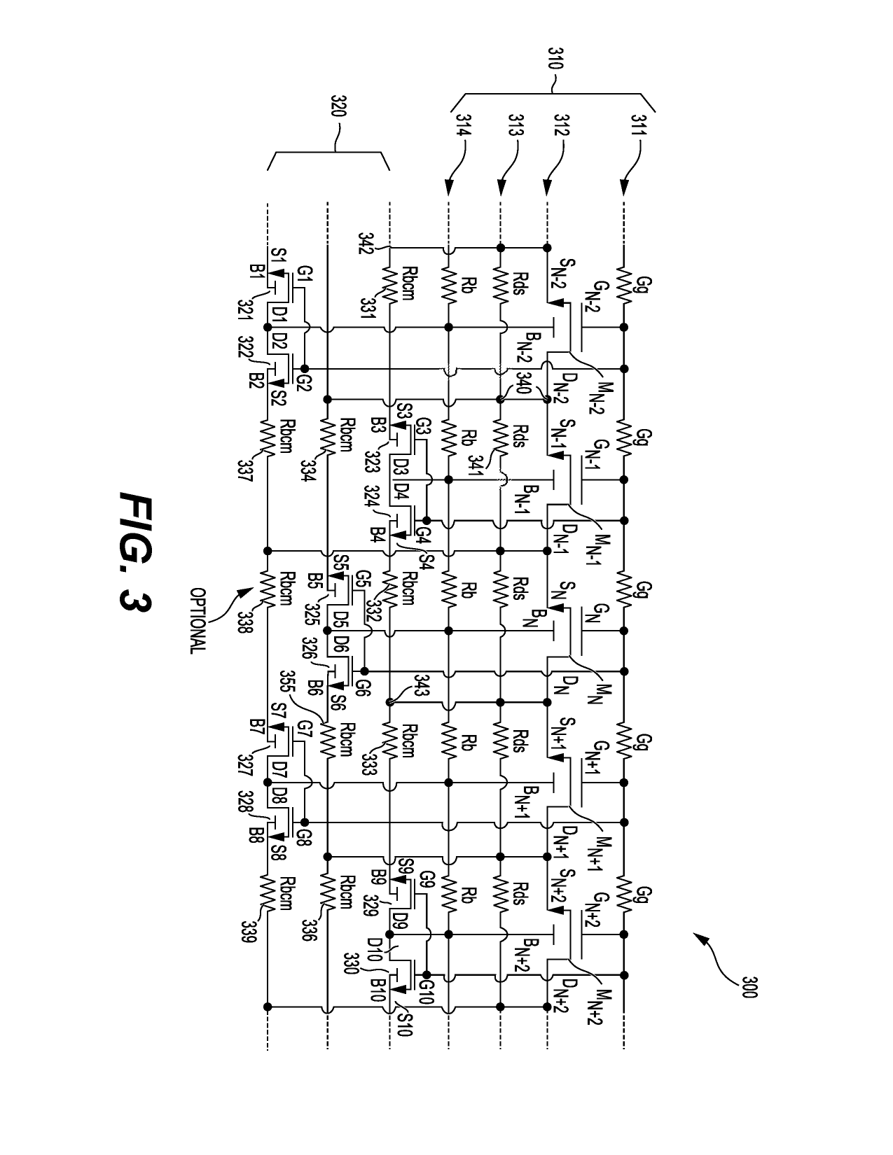

FIG. 3 shows a diagram of a section of an RF switch 300 according to some embodiments of the present disclosure. The RF switch has an upper portion and a lower portion. The upper portion corresponds to an RF switch circuit 310. The lower portion corresponds to a BCM circuit 320. The RF switch circuit 310 includes a gate bias network 311, a FET stack 312, a drain-to-source resistor network 313, and a body bias network 314. The RF switch circuit 310 can have a first port and a second port (not shown). The FET stack 312 is disposed between the first port and the second port.

The FET stack 312 includes FETs M_{N-2} through M_{N+2} connected in series. These FETs can be turned on or off by applying suitable gate bias voltages through the gate bias network 311 to achieve the switching function of the RF switch 300. These FETs can be referred to as switch FETs, to distinguish them from BCM FETs in the BCM circuit 320.

The switch FETs each share a portion of an RF load voltage imposed on the FET stack 312. Each switch FET in the FET stack 312 has a gate, a source, a drain, and a body. For example, the switch FET M_{N} has a gate G_{N}, a source S_{N}, a drain D_{N}, and a bodyB_{N}, and the FET M_{N-2} has a gate G_{N-2}, a source S_{N-2}, a drain D_{N-2}, and a bodyB_{N-2}, as shown in FIG. 3. The drain and source of two neighboring switch FETs in the FET stack 312 are connected together, thereby forming the FET stack 312. While five switch FETs are shown in FIG. 3, the RF switch 300 can include any number of switch FETs, such as 1, 2, 8, 12, and so on. Accordingly, other components in the RF switch circuit 310 and the BCM circuit 320 can be scaled according to the number of switch FETs.

The gate bias network 311 supplies bias voltages to the gates of the respective switch FETs through a series of gate bias resistors Rg. The drain-to-source resistor network 313 (including drain-to-source resistors Rds) helps to provide the DC bias to the drain and source nodes of the switch FETs in the FET stack 312. The body bias network 314 supplies body bias voltages to the FETs through a series of body bias resistors Rb.

The BCM circuit 320 includes BCM FETs 321-330. Each switch FET in the FET stack 312 is associated with a pair of BCM FETs. For example, the switch FET M_{N-2} is associated with the BCM FETs 321 and 322. The switch FET M_{N-1} is associated with the BCM FETs 323 and 324. The switch FET M_{N} is associated with the BCM FETs 325 and 326. The switch FET M_{N+1} is associated with the BCM FETs 327 and 328. The switch FET M_{N+2} is associated with the BCM FETs 329 and 330.

For each switch FET in the FET stack 312, drains of the corresponding pair of BCM FETs are coupled to the body of the switch FET, and gates of the corresponding pair of BCM FETs are coupled to the gate bias network 311. Sources of the corresponding pair of the BCM FETs are coupled to nodes in the drain-to-source resistor network 313 and the FET stack 312.

For example, for the switch FET M_{N}, drains D5 and D6 of the BCM FETs 325 and 326 are coupled to the body B_{N} of the switch FET M_{N}. Gates G5 and G6 of the BCM FETs 325 and 326 are coupled to the gate G_{N} of the switch FET M_{N}. The source S5 of the BCM FET 325 is coupled, via a resistor Rbcm 334, to the source S_{N-1} of the switch FET M_{N-1} that neighbors the switch FET M_{N} at the left side. The source S6 of the BCM FET 326 is coupled, via a resistor Rbcm 335, to the drain D_{N+1} of the switch FET M_{N+1} that neighbors the switch FET M_{N} at the right side. The body of each BCM FET is connected to the source of the same BCM FET. In other implementations, the body of each BCM FET can be left floating or connected to another potential through another bias network.

In operation, the RF switch 300 can be placed into an off state (i.e., open) by applying suitable gate voltages to each switch FET in the FET stack 312 through the gate bias network 311. When a high RF voltage is applied to the RF switch 300 between the first port and the second port, body current may be generated within the switch FETs in the FET stack 312. Taking the FET M_{N} as an example, the body current initially flows through the corresponding body bias resistor Rb, raising the body voltage of the FET M_{N}. As the body voltage increases beyond a certain threshold, the corresponding BCM FET 325 or 326 starts conducting. The body current is then diverted away from the body bias resistor Rb and rerouted through the BCM FET 325 or 326 to the drain-to-source resistor network 313, where the power of the body current is dissipated. In this way, the BCM circuit 320 can maintain the body voltage at a more stable level in response to RF voltage swings, thereby reducing signal non-linearity and avoiding early breakdown of the RF switch FETs. The BCM mechanism of the RF switch 300 is based on BCM FETs and thus is referred to as FET BCM.

The RF signal power or voltage level at which the BCM circuit 320 activates is referred to as the BCM turn-on threshold. In a FET-based BCM implementation, the BCM turn-on threshold can be adjusted by modifying the physical dimensions of the BCM FET (i.e., sizing), selecting an appropriate threshold voltage (Vt), or using other mechanisms disclosed herein. Compared to diode-based or replica-based BCM circuits, the FET-based BCM offers more tunable circuit parameters, enabling finer control and more precise adjustment of the BCM turn-on threshold.

Components in the BCM circuit 320 can be integrated with each individual switch FET as a unit cell. For example, the pair of BCM FETs 325 and 326, optionally together with the resistors Rbcm 334 and 335, can be grouped with the switch FET M_{N} to form a unit cell. Accordingly, the RF switch can easily be scaled for any switch stack height (the number of FETs in the switch stack).

In FIG. 3, the source of a BCM FET is shown coupled to a node shared by a source or drain of a switch FET and a drain-to-source resistor Rds. For example, the source S5 of the BCM FET 325 is coupled to a node 340 which is shared by the source S_{N-1} of the switch FET M_{N-1} and the drain-to-source resistor Rds 341. In other embodiments, the drain-to-source resistor network 313 may have a different structure, and the source S5 of the BCM FET 325 is coupled to a node of the drain-to-source resistor network 313 that is not located between two neighboring switch FETs. In some embodiments, the source of a BCM FET is coupled to a resistor network separate from the drain-to-source resistor network 313 or the FET stack 312, such as the resistor string 222 shown in FIG. 2.

While the gate of each BCM FET is shown connected to a gate of a corresponding switch FET in FIG. 3, the gate of each BCM FET can be connected to a node in the gate bias network 311 that is not shared by a gate of the corresponding switch FET in one embodiment.

The series resistors Rbcm 331-339 are each arranged in the path of the body current flowing from a respective BCM FET. The series resistor Rbcm can function as an electrostatic discharge (ESD) protection resistor. In one embodiment, no series resistor is configured in the BCM circuit 320. In one embodiment, a diode stack is arranged in place of the series resistor Rbcm. In one embodiment, a diode stack is added in series to the resistor Rbcm. The diode stack can be employed to fine-tune the BCM turn-on threshold.

In some embodiments, for a switch FET located at an end of the FET stack 312 connected to one of the RF switch ports (the first port or the second port), the BCM circuit 320 can be configured as follows. For example, if the switch FET G_{N-2} is the first FET in the FET stack 312, the BCM FET 321 can be omitted. Similarly, if the switch FET G_{N+2} is the last FET in the FET stack 312, the BCM FET 330 can be omitted. In another implementation.

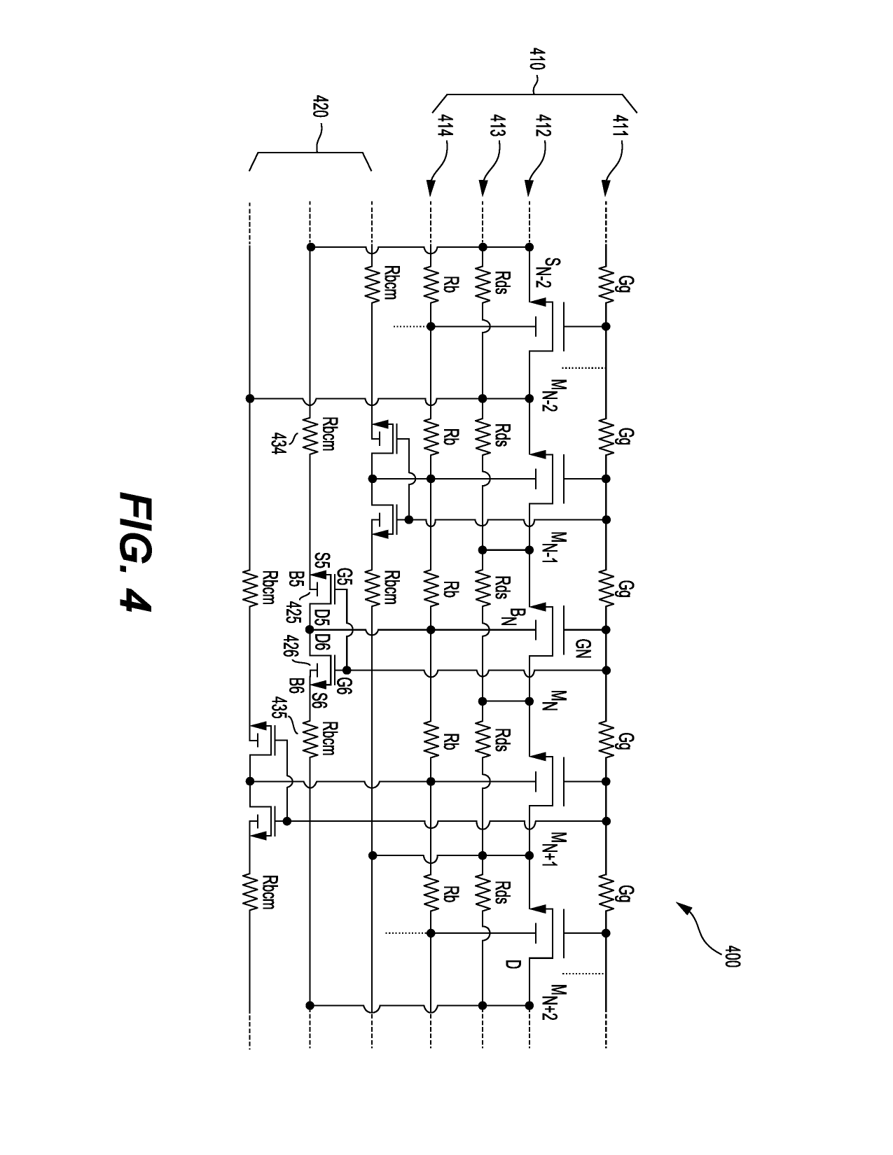

FIG. 4 shows another embodiment for an RF switch with BCM FET. FIG. 4 shows a diagram of a section of an RF switch 400. The RF switch 400 includes an RF switch circuit 410 which has a similar structure to the RF switch circuit 310 of FIG. 3. Similarly, the RF switch circuit 410 includes a gate bias network 411, a FET stack 412, a drain-to-source resistor network 413, and a body bias network 414. The RF switch 400 further includes a BCM circuit 420. As in the previous embodiment of FIG. 3, each switch FET in the FET stack 412 is associated with a pair of BCM FETs to reroute a body current. For example, for the switch FET M_{N}, drains D5 and D6 of the BCM FETs 425 and 426 are coupled to the body B_{N} of the switch FET M_{N} and gates G5 and G6 of the BCM FETs 425 and 426 are coupled to the gate G_{N} of the switch FET M_{N}.

Unlike the BCM circuit 320 in FIG. 3, the sources of the BCM FETs 425 and 426 in FIG. 4 are coupled to a source or drain of a switch FET that is not a direct neighbor of the switch FET M_{N}. For example, the source S5 of the BCM FET 425 is coupled, via a resistor Rbcm 434, to the source S_{N-2} of the switch FET M_{N-2} that does not neighbor the switch FET M_{N}. The source S6 of the BCM FET 426 is coupled, via a resistor Rbcm 435, to the drain D_{N+2} of the switch FET M_{N+2} that is separated from the switch FET M_{N} by the switch FET M_{N+1}.

Connecting the source of a BCM FET to a different position (different switch FET) in a FET stack (i.e., to a non-adjacent switch FET) provides an additional option for fine tuning the BCM turn-on threshold.

According to the present disclosure, the BCM FET is turned on by the rising gate voltage of the stack switch FET. This provides more precise control over the turn-on voltage of the BCM FET, unlike other mechanisms where the BCM diode is directly controlled by the body voltage of the stack FET.

In addition, the BCM FET turn-on voltage can be adjusted by modifying its threshold voltage, such as by selecting the device type or adjusting its channel length. In contrast, the body current management mechanism using diodes offers limited flexibility in tuning the turn-on voltage.

Further, the body current of the switch FET is directed through the drain-source path of the BCM FET. The voltage across this junction can be significantly higher than the voltage across the diode(s) used in other mechanisms, enabling improved maximum RF power before breakdown occurs.

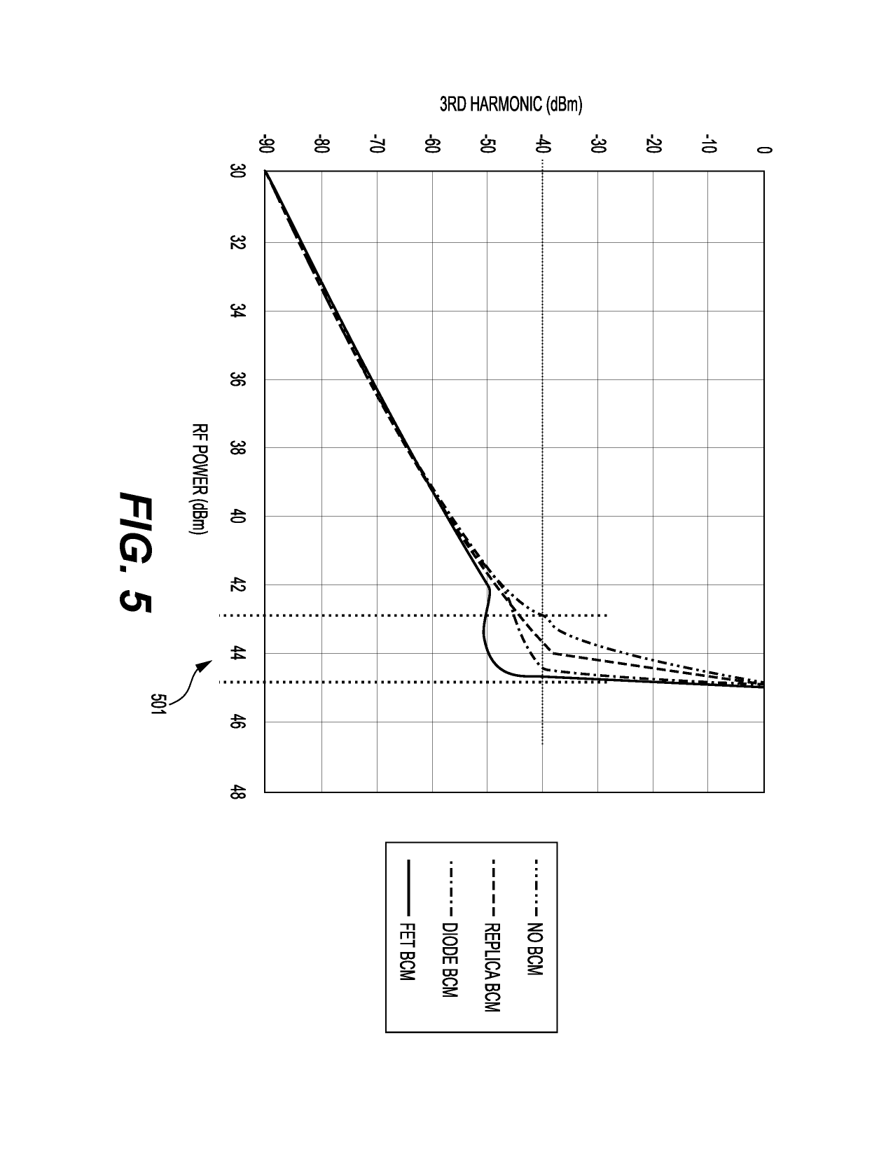

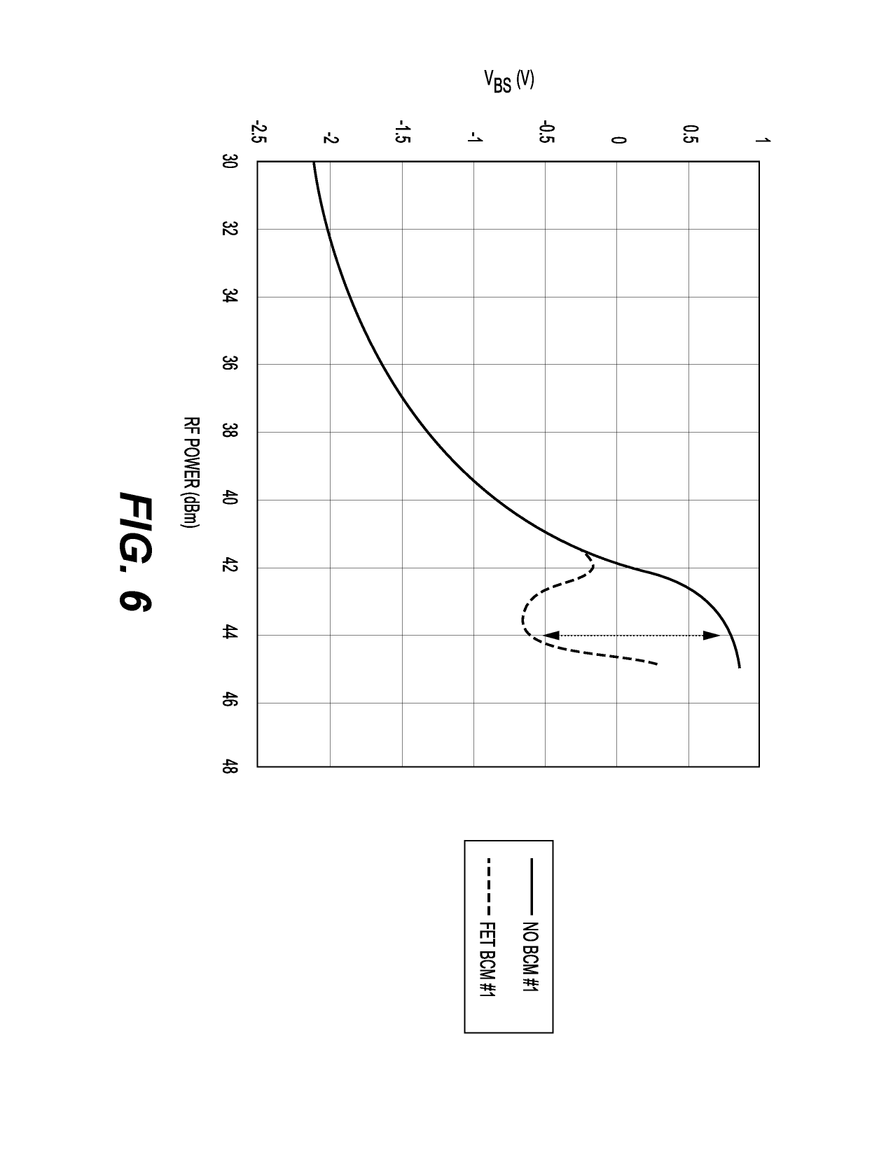

FIG. 5 and FIG. 6 show test results for an RF switch implementing the BCM FET mechanism disclosed herein. RF switches employing different body current management schemes are tested and compared. The tested RF switches are configured with different body current management circuits: FET BCM, diode BCM, replica BCM, or no BCM. In the test setup, the RF switch under test is placed in an off state and connected in parallel with a load. The power of an RF signal source is gradually increased from 30 dBm to 50 dBm,. The third harmonic power generated due to non-linearities in the RF switch is measured. The linearity of the FET stack in the RF switch is represented by the third harmonic power level (H3).

The diagram of FIG. 5 shows improved linearity performance for the FET BCM compared to the diode BCM, replica BCM, or the case with no BCM. Four curves are plotted in FIG. 5, each showing the relationship between measured H3 and the applied RF input power. As shown, for an H3 specification of -40 dBm, the FET BCM improves operational peak input RF power (or voltage) by 2 dBm, raising it from 43 dBm (no BCM) to 45 dBm (with FET BCM). Near the breakdown region 501 on the RF power axis, the FET BCM improves H3 by more than 10 dBm when compared to the configuration without BCM.

The diagram in FIG. 6 shows improved drain-body/source-body junction bias voltages of a switch FET when using the FET BCM, compared the configuration with no BCM. Two curves are plotted in FIG. 6, each showing the relationship between measured body-source voltage Vbs and the applied RF input power. The switch FET Stack linearity derives from the behavior of the drain-body and source-body junction diodes. By maintaining the reverse bias junction voltages far away from diode turn-on threshold, the FET BCM technique improves junction linearity and extends the operational maximum power of the Switch FET stack. For example, at +44 dBm RF power, the body-source junction voltage of the top FET (M1) in the switch FET stack is reduced by more than 1 V, allowing the switch FET stack to be driven by a higher signal power until the junction breakdown power is reached.

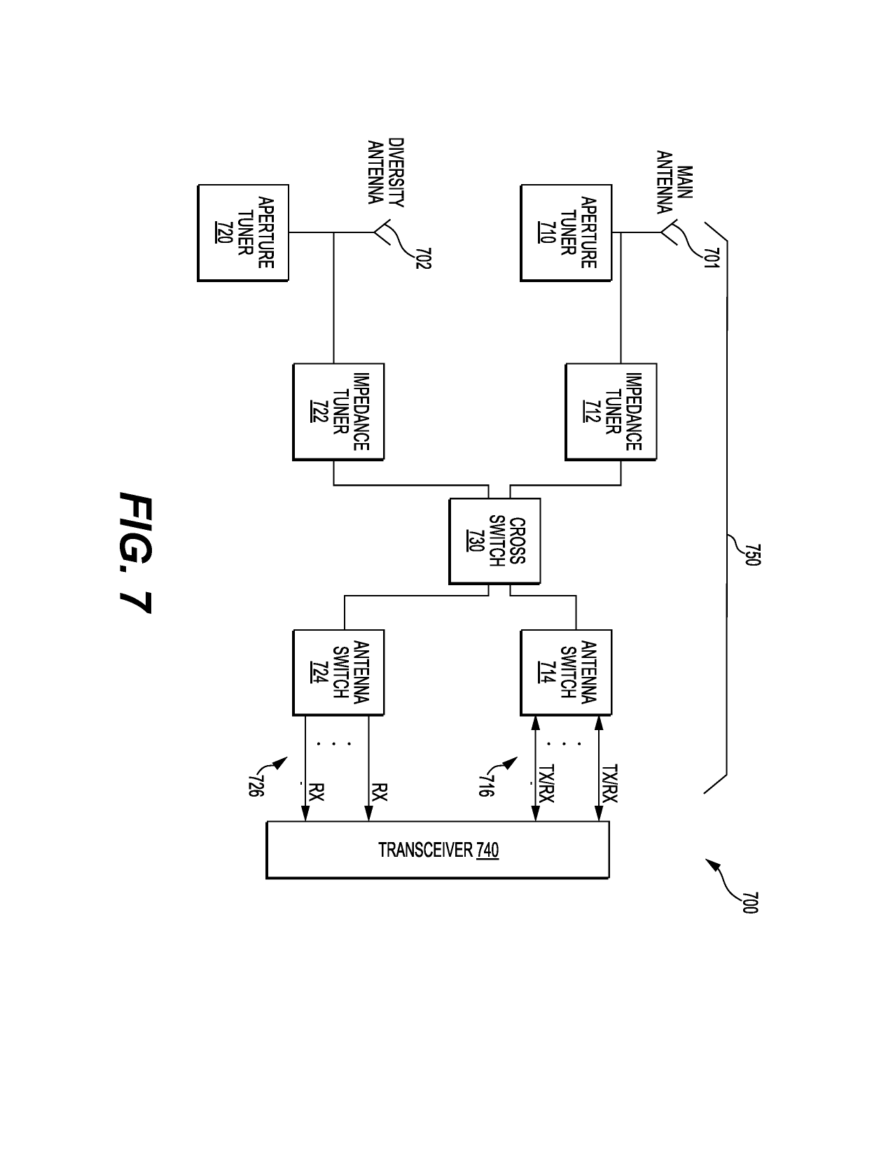

FIG. 7 shows an example mobile device 700 implementing an RF front-end 750 according to embodiments of the present disclosure. The mobile device 700 can be configured to support carrier aggregation and multiple-input, multiple-output MIMO operation. The RF front-end 750 is coupled to a transceiver 740. The RF front-end 750 can include a main antenna 701 and a diversity antenna 702. The main antenna 701 provides a primary transceiver path for both transmit (TX) and receive (RX) signals. The diversity antenna 702 is used for receiving signals, for example, to improve reception reliability.

The main antenna 701 can be configured with an aperture tuner 710 and an impedance tuner 712. The diversity antenna 702 can be configured with an aperture tuner 720 and an impedance tuner 722. In the aperture tuners 710 and 720, RF switches with FET BCM are used to selectively connect or disconnect tuning elements, such as capacitive or inductive components, to modify the electrical length or resonance characteristics of the chassis or ground plane. In the impedance tuners 712 and 722, RF switches with FET BCM are used to selectively engage or disengage reactive components to modify the impedance seen by the antenna 701 or 702.

The RF front-end 750 further includes a cross switch 730. The cross switch 730 includes RF switches with FET BCM and is configured to reroute RF signal paths between the main antenna 701 and the diversity antenna 702. By dynamically switching connections between different transmit and receive paths, the cross switch 730 enables flexible antenna sharing, signal path optimization, and dynamic configuration of the RF front-end 750.

The RF front-end 750 further includes a first antenna switch 714 and a second antenna switch 724 to support carrier aggregation. The first antenna switch 714 is coupled to the cross switch 730 at one side and interfaces with bi-directional signal chains 716 at the other side. Each bi-directional signal chain 716 can carry both Tx and Rx signals using a duplexer. Each bi-directional signal chain 716 can correspond to a carrier. These bi-directional signal chains are coupled between the antenna switch 714 and the transceiver 740, enabling time-division or frequency-division operation depending on the selected communication mode. The RF switches within the antenna switch 714 may also implement the FET BCM mechanism disclosed herein.

The second antenna switch 724 is also coupled to the cross switch 730 at one side and interfaces with receive-only signal chains 726 at the other side. The signal chains 726 provide signals to the transceiver 740 and can operate in different carriers for carrier aggregation operation. These Rx signal chains 726 are optimized for low-noise performance and are used in MIMO reception or diversity reception modes in one example. Like the first antenna switch 714, the second antenna switch 724 may also include RF switches with FET BCM to preserve linearity under high-power conditions.

The transceiver 740 is configured to support simultaneous operation over multiple frequency bands for both uplink and downlink, enabling carrier aggregation across different combinations of intra-band or inter-band carriers. The transceiver 740 communicates with both the bi-directional signal chains 716 and the Rx signal chains 726. In some embodiments, the transceiver 740 dynamically controls the cross switch 730, antenna switches 714 and 724, and antenna tuning elements 710, 712, 720, and 722 to configure the RF front-end according to network demands, antenna conditions, and device usage scenarios.

In an embodiment, the mobile device 700 is capable of adapting its antenna paths for optimal performance under various wireless standards, including 4G LTE, 5G NR, and future air interfaces. The use of RF switches with FET BCM ensures high reliability, reduced harmonic distortion, and improved power handling at the RF front-end 750.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

What is claimed is:

1. A radio frequency (RF) switch, comprising:
a first field-effect transistor (FET) that is part of an RF switch FET stack, the first FET having a source, a drain, a gate, and a body, the gate of the first FET being connected to a gate bias network that is configured to control an on/off state of the RF switch FET stack; and
a first body current management (BCM) FET and a second BCM FET each having a source, a drain, and a gate,
wherein the drains of the first BCM FET and the second BCM FET are coupled to the body of the first FET, and the gates of the first BCM FET and the second BCM FET are coupled to the gate bias network.

2. The RF switch of claim 1, wherein the sources of the first BCM FET and the second BCM FET are coupled directly or indirectly to nodes in the RF switch FET stack.

3. The RF switch of claim 1, wherein the gates of the first BCM FET and the second BCM FET are coupled to the gate of the first FET.

4. The RF switch of claim 1, further comprising a second FET and a third FET that are part of the RF switch FET stack,
wherein the second FET, the first FET, and the third FET are coupled in series, the source of the first FET is coupled to a drain of the second FET, and the drain of the first FET is coupled to a source of the third FET, and
a source of the first BCM FET is coupled to a source of the second FET, and a source of the second BCM FET is coupled to a drain of the third FET.

5. The RF switch of claim 1, further comprising a second FET and a third FET in the RF switch FET stack and a first resistor,
wherein the second FET, the first FET, and the third FET are coupled in series, the source of the first FET is coupled to a drain of the second FET, and the drain of the first FET is coupled to a source of the third FET, and
the first resistor is coupled between a source of the first BCM FET and a source of the second FET.

6. The RF switch of claim 5, further comprising a second resistor that is coupled between a source of the second BCM FET and a drain of the third FET.

7. The RF switch of claim 5, further comprising one or more diodes connected in series that are coupled between the source of the first BCM FET and the source of the second FET in series with the first resistor.

8. The RF switch of claim 1, further comprising a second FET and a third FET in the RF switch FET stack and one or more first diodes,
wherein the second FET, the first FET, and the third FET are coupled in series, the source of the first FET is coupled to a drain of the second FET, and the drain of the first FET is coupled to a source of the third FET, and
the one or more first diodes are connected in series and coupled between a source of the first BCM FET and a source of the second FET.

9. The RF switch of claim 8, further comprising one or more second diodes connected in series that are coupled between a source of the second BCM FET and a drain of the third FET.

10. The RF switch of claim 1, comprising 5 FETs in the RF switch FET stack that each include a source and a drain and are coupled in series, wherein the first FET is the middle one of the 5 FETs, and the source and the drain of each pair of neighboring ones of the 5 FETs are coupled together, and
a source of the first BCM FET is coupled to the source of the first one of the 5 FETs, and a source of the second BCM FET is coupled to the drain of the last one of the 5 FETs.

11. The RF switch of claim 1, comprising N FETs in the RF switch FET stack that each include a source and a drain and are coupled in series,
wherein N is an integer greater than 2, and the source and the drain of each pair of neighboring ones of the N FETs are coupled together, and
a source of the first BCM FET is coupled to a source or drain of a non-adjacent FET in the RF switch FET stack, and a source of the second BCM FET is coupled to a source or drain of another non-adjacent FET in the RF switch FET stack.

12. The RF switch of claim 1, comprising 5 FETs in the RF switch FET stack and a first resistor, wherein the 5 FETs each include a source and a drain and are coupled in series, the first FET is the middle one of the 5 FETs, and the source and the drain of each pair of neighboring ones of the 5 FETs are coupled together, and
the first resistor is coupled between a source of the first BCM FET and a source of the first one of the 5 FETs.

13. The RF switch of claim 12, further comprising a second resistor that is coupled between a source of the second BCM FET and a drain of the last one of the 5 FETs.

14. The RF switch of claim 12, further comprising one or more diodes connected in series that are coupled between the source of the first BCM FET and the source of the first one of the 5 FETs in series with the first resistor.

15. The RF switch of claim 1, comprising 5 FETs in the RF switch FET stack and one or more first diodes, wherein the 5 FETs each include a source and a drain and are coupled in series, the first FET is the middle one of the 5 FETs, and the source and the drain of each pair of neighboring ones of the 5 FETs are coupled together, and
the one or more first diodes are connected in series and coupled between a source of the first BCM FET and a source of the first one of the 5 FETs.

16. The RF switch of claim 15, further comprising one or more second diodes connected in series that are coupled between a source of the second BCM FET and a drain of the last one of the 5 FETs.

17. A wireless communication device, comprising a radio frequency (RF) switch that comprises:
a first field-effect transistor (FET) that is part of an RF switch FET stack, the first FET having a source, a drain, a gate, and a body, the gate of the first FET being connected to a gate bias network that is configured to control an on/off state of the RF switch FET stack; and
a first body current management (BCM) FET and a second BCM FET each having a source, a drain, and a gate,
wherein the drains of the first BCM FET and the second BCM FET are coupled to the body of the first FET, the gates of the first BCM FET and the second BCM FET are coupled to the gate bias network.

18. The wireless communication device of claim 17, wherein the sources of the first BCM FET and the second BCM FET are coupled directly or indirectly to different nodes in the RF switch FET stack.

19. The wireless communication device of claim 17, wherein the gates of the first BCM FET and the second BCM FET are coupled to the gate of the first FET.

20. The wireless communication device of claim 17, wherein the RF switch further comprises a second FET and a third FET in the RF switch FET stack,
the second FET, the first FET, and the third FET are coupled in series, the source of the first FET is coupled to a drain of the second FET, and the drain of the first FET is coupled to a source of the third FET, and
a source of the first BCM FET is coupled to a source of the second FET, and a source of the second BCM FET is coupled to a drain of the third FET.
